(19) United States
(12) Patent Application Publication
(10) Pub. No.: US 2026/0015725 A1
(43) Pub. Date: Jan. 15, 2026

(54) STORAGE CONTAINER, SUBSTRATE PROCESSING APPARATUS, GAS SUPPLY METHOD AND METHOD OF MANUFACTURING SEMICONDUCTOR DEVICE

(71) Applicant: Kokusai Electric Corporation, Tokyo (JP)

(72) Inventors: Kenji FURUMURA, Toyama-shi (JP); Kentaro GOSHIMA, Toyama-shi (JP); Masashi HORI, Toyama-shi (JP); Ayako SHINMURA, Toyama-shi (JP); Shinji NOZAWA, Toyama-shi (JP)

(73) Assignee: Kokusai Electric Corporation, Tokyo (JP)

(21) Appl. No.: 19/335,248

(22) Filed: Sep. 22, 2025

Related U.S. Application Data
(63) Continuation of application No. PCT/JP2023/034380, filed on Sep. 21, 2023.

(51) Int. Cl. C23C 16/455; C23C 16/44

(52) U.S. Cl. CPC C23C 16/45591; C23C 16/4412

(57) ABSTRACT

There is provided a technique that includes a storage container provided in a supply line through which a source gas is supplied to a process chamber, the storage container including: a storage structure capable of storing the source gas therein, wherein a flow path cross-sectional area of the storage structure is set to be greater than that of the supply line; and a partition structure arranged inside the storage structure along a gas flow direction, and configured to partition an inside of the storage structure by passing through a radial central portion of the storage structure when viewed from the gas flow direction such that a plurality of flow paths are formed.

### CROSS-REFERENCE TO RELATED PATENT APPLICATION

This application is a bypass continuation application of PCT International Application No. PCT/JP2023/034380, filed on Sep. 21, 2023, in the WIPO, the entire contents of which are hereby incorporated by reference.

### BACKGROUND

### 1. Field

The present disclosure relates to a storage container, a substrate processing apparatus, a gas supply method and a method of manufacturing a semiconductor device.

### 2. Related Art

According to some related arts, a part of a manufacturing process of a semiconductor device, when a source gas or a reactive gas is supplied to a substrate to form a film on the substrate, a substrate processing may be performed by supplying a large amount of the source gas at once in a very short time (that is, by using a flash supply). However, an adiabatic expansion caused by such a flash supply may affect the substrate processing.

### SUMMARY

According to the present disclosure, there is provided a technique capable of reducing an effect of an adiabatic expansion caused by a flash supply.

According to an embodiment of the present disclosure, there is provided a technique that includes: a storage container provided in a supply line through which a source gas is supplied to a process chamber, the storage container including: a storage structure capable of storing the source gas therein, wherein a flow path cross-sectional area of the storage structure is set to be greater than that of the supply line; and a partition structure arranged inside the storage structure along a gas flow direction, and configured to partition an inside of the storage structure by passing through a radial central portion of the storage structure when viewed from the gas flow direction such that a plurality of flow paths are formed.

### BRIEF DESCRIPTION OF THE DRAWINGS

FIG. 1 is a diagram schematically illustrating a substrate processing apparatus preferably used in one or more embodiments of the present disclosure.

FIG. 2 is a diagram schematically illustrating a horizontal cross-section, taken along a line A-A shown in FIG. 1, of the substrate processing apparatus preferably used in the embodiments of the present disclosure.

FIG. 3 is a block diagram schematically illustrating a configuration of a controller 121 and its related components of the substrate processing apparatus preferably used in the embodiments of the present disclosure.

FIG. 4 is a flow chart schematically illustrating a film forming sequence according to the embodiments of the present disclosure.

FIG. 5A is a diagram schematically illustrating an exploded perspective view of a storage container according to the embodiments of the present disclosure.

FIG. 5B is a diagram schematically illustrating a cross-section, taken along a line 5B-5B in FIG. 5A, of the storage container according to the embodiments of the present disclosure.

FIG. 5C is a diagram schematically illustrating a plan view of an inlet structure of the storage container when viewed from a gas flow direction.

FIG. 5D is a diagram schematically illustrating a plan view of an outlet structure of the storage container when viewed from the gas flow direction.

FIG. 6A is a diagram schematically illustrating a first modified example of the storage container according to the embodiments of the present disclosure.

FIG. 6B is a diagram schematically illustrating a second modified example of the storage container according to the embodiments of the present disclosure.

FIG. 6C is a diagram schematically illustrating a third modified example of the storage container according to the embodiments of the present disclosure.

FIG. 7 is a diagram schematically illustrating a fourth modified example of the storage container according to the embodiments of the present disclosure.

FIG. 8 is a diagram schematically illustrating a relationship among a time, a pressure and a temperature after a flash supply with respect to a storage container according to a comparative example.

FIG. 9 is a diagram schematically illustrating a simulation result showing a temperature decrease due to an adiabatic expansion after a flash supply with respect to the storage container according to the embodiments of the present disclosure.

FIG. 10 is a diagram schematically illustrating a storage container according to another embodiment of the present disclosure.

### DETAILED DESCRIPTION

### Embodiments of Present Disclosure

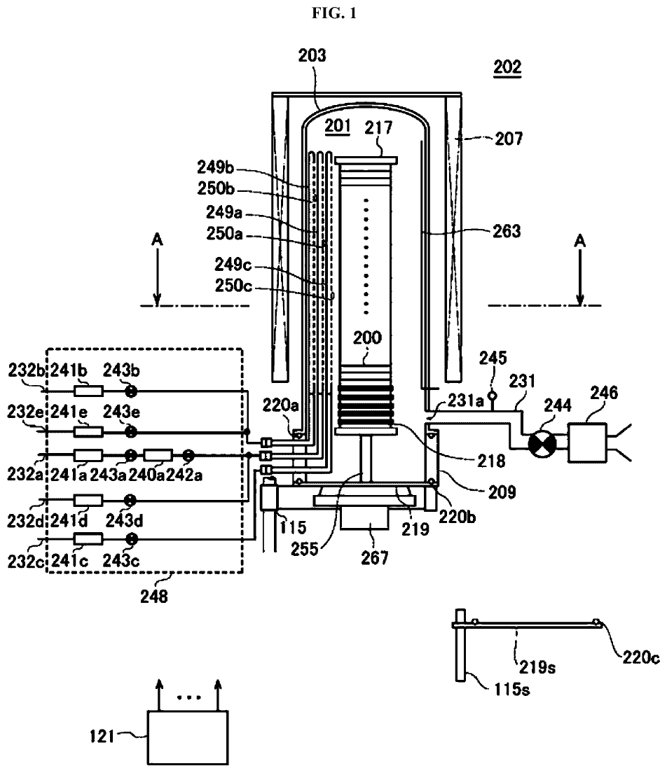

Hereinafter, one or more embodiments (hereinafter, also simply referred to as “embodiments”) according to the present disclosure will be described mainly with reference to FIGS. 1 to 7. For example, the drawings used in the following description are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

As shown in FIG. 1, a process furnace 202 of a substrate processing apparatus according to the present embodiments may include a heater 207 serving as a temperature regulator (which is a temperature adjusting structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers 200. Hereinafter, each of the plurality of wafers 200 may also be simply referred to as a “wafer 200” which serves as a substrate. The wafer 200 is processed in the process chamber 201.

Nozzles 249a, 249b and 249c are provided in the process chamber 201 so as to penetrate a side wall of the manifold 209. The nozzles 249a, 249b and 249c may serve as a first supply structure, a second supply structure and a third supply structure, respectively. The nozzles 249a, 249b and 249c may also be referred to as a first nozzle, a second nozzle and a third nozzle, respectively. For example, each of the nozzles 249a, 249b and 249c is made of a heat resistant material such as quartz and silicon carbide (SiC). Gas supply pipes 232a, 232b and 232c are connected to the nozzles 249a, 249b and 249c, respectively. The nozzles 249a, 249b and 249c are different nozzles, and the nozzles 249b and 249c are provided adjacent to the nozzle 249a such that the nozzle 249a is interposed between the nozzles 249b and 249c.

A mass flow controller (also simply referred to as an “MFC”) 241a serving as a flow rate controller (flow rate control structure), a valve 243a serving as an opening/closing valve, a storage (which is a storage container or a reservoir) 240a serving as a source material vessel capable of storing a gas and a valve 242a serving as an opening/closing valve are sequentially installed at the gas supply pipe 232a in this order from an upstream side to a downstream side of the gas supply pipe 232a in a gas flow direction.

A gas supply pipe 232d is connected to the gas supply pipe 232a at a downstream side of the valve 242a of the gas supply pipe 232a. An MFC 241d and a valve 243d are sequentially installed at the gas supply pipe 232d in this order from an upstream side to a downstream side of the gas supply pipe 232d in the gas flow direction. For example, the gas supply pipes 232a and 232d and the storage 240a are made of a metal material such as SUS.

The storage 240a is configured such that a flow path cross-sectional area thereof is greater than that of a normal pipe (normal piping). For example, the storage 240a is configured as a gas tank whose gas capacity is greater than that of the normal pipe. The storage 240a is configured to be capable of filling the storage 240a with the gas supplied through the gas supply pipe 232a and supplying the gas filled in the storage 240a to the process chamber 201 by opening and closing the valve 243a provided at an upstream of the storage 240a and the valve 242a provided at a downstream of the storage 240a.

<Storage 240a>

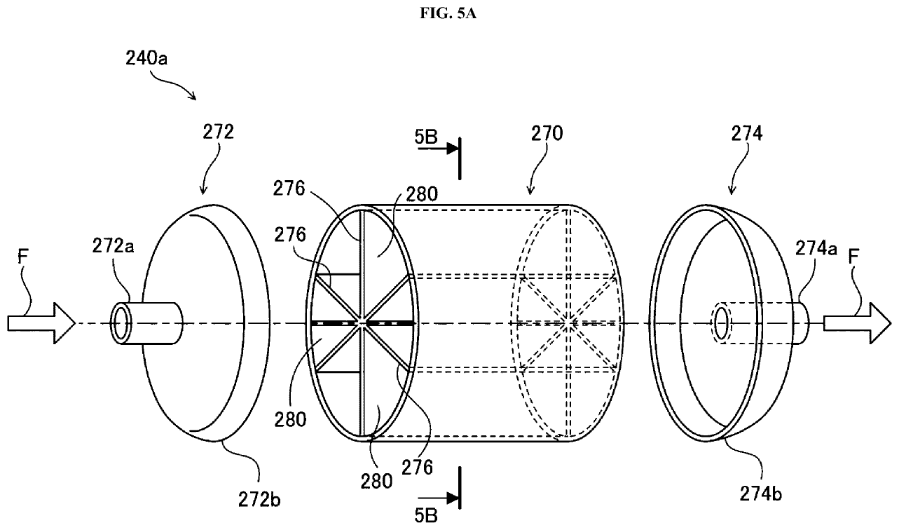

The storage 240a will be described in detail using FIGS. 5A and 5B. The storage 240a is a storage container (gas tank) provided in a source gas supply line (described later) through which a source gas is supplied to the process chamber 201. As shown in FIG. 5A, the storage 240a includes a storage structure 270, an inlet structure 272, an outlet structure 274 and a partition structure 276. The source gas is introduced into the storage structure 270 through the inlet structure 272 serving as a part of the storage 240a. The storage structure 270 serving as a part of the storage 240a is configured to be capable of storing the source gas therein. The source gas is released (or ejected) from the storage structure 270 through the outlet structure 274 serving as a part of the storage 240a. As described later, the storage 240a may further include one or more partition structures substantially the same as the partition structure 276. Hereinafter, the one or more partition structures and the partition structure 276 may also be collectively or individually referred to as “partition structures 276” or the “partition structure 276”.

### <Storage Structure 270>

As shown in FIG. 5B, a flow path cross-sectional area of the storage structure 270 is set to be greater than a flow path cross-sectional area of the source gas supply line. In addition, the storage structure 270 is configured such that the source gas can be (temporarily) stored inside the storage structure 270. The partition structure 276 is disposed inside the storage structure 270.

### <Inlet Structure 272>

As shown in FIG. 5A, the inlet structure 272 includes: an introduction structure 272a into which the source gas is introduced; and a connecting structure (which is a connector) 272b configured to connect the introduction structure 272a and the storage structure 270. A flow path cross-sectional area of the introduction structure 272a is set to be the same as the flow path cross-sectional area of the source gas supply line. On the other hand, the flow path cross-sectional area of the introduction structure 272a is different from a flow path cross-sectional area of the connecting structure 272b. Specifically, the flow path cross-sectional area of the connecting structure 272b is set to be greater than the flow path cross-sectional area of the introduction structure 272a. In addition, the connecting structure 272b according to the present embodiments is of a bowl shape.

### <Outlet Structure 274>

As shown in FIG. 5A, the outlet structure 274 includes: a release structure 274a from which the source gas is released (or ejected); and a boundary structure 274b configured to connect the release structure 274a and the storage structure 270. A flow path cross-sectional area of the release structure 274a is set to be the same as the flow path cross-sectional area of the source gas supply line. On the other hand, the flow path cross-sectional area of the release structure 274a is different from a flow path cross-sectional area of the boundary structure 274b. Specifically, the flow path cross-sectional area of the boundary structure 274b is set to be greater than the flow path cross-sectional area of the release structure 274a. In addition, the boundary structure 274b according to the present embodiments is of a bowl shape.

According to the present embodiments, the flow path cross-sectional area of each of the introduction structure 272a and the release structure 274a is different from the flow path cross-sectional area of the storage structure 270. However, since the connecting structure 272b and the boundary structure 274b are of the same shape (that is, of the same bowl shape), it is possible to perform a flash supply of the source gas without impeding a flow of the source gas. In addition, since the inlet structure 272 and the outlet structure 274 are of the same shape, it is possible to reduce the number of components constituting the storage 240a.

### <Partition Structure 276>

As shown in FIG. 5A, the partition structure 276 is arranged inside the storage structure 270 to extend along the gas flow direction. In addition, when viewed from the gas flow direction (see FIG. 5B), the partition structure 276 is configured to partition an inside (inner portion) of the storage structure 270 to form (or provide) a plurality of flow paths 280. Specifically, by dividing (or partitioning) the inside of the storage structure 270 into a plurality of sections when viewed from the gas flow direction, it is possible to form the flow paths 280. The source gas introduced into the storage 240a passes through the flow paths 280. In addition, according to the present embodiments, the partition structure 276 is of a plate shape.

In the present specification, the term “gas flow direction” refers to a direction in which the source gas flows inside the storage 240a. In other words, the gas flow direction is a direction in which the source gas introduced through the introduction structure 272a flows until the source gas is released from the release structure 274a. According to the present embodiments, the gas flow direction is a direction along an axial direction of the storage structure 270. The gas flow direction is indicated by an arrow F in FIG. 5A.

In addition, the partition structure 276 passes through a radial central portion 271 of the storage structure 270 when viewed from the gas flow direction. Specifically, the partition structure 276 partitions (or divides) the inside of the storage structure 270 (including the radial central portion 271 of the storage structure 270) when viewed from the gas flow direction.

In the present specification, the term “central portion” refers to a portion which is not easily heated by a piping heater 248 provided outside a pipe (piping) and is easily affected by a temperature decrease due to an adiabatic expansion described later. That is, the radial central portion 271 of the storage structure 270 includes a center C of the storage structure 270, and further includes a range indicated by a circular cross-section whose radius r from the center C is less than a quarter (¼) of a diameter D of the storage structure 270.

As shown in FIG. 5B, the partition structure 276 partitions the inside of the storage structure 270 such that two or more of the flow paths 280 whose flow path cross-sectional areas are the same can be provided. According to the present embodiments, for example, the partition structure 276 partitions the inside of the storage structure 270 to form (or provide) eight flow paths 280. That is, for example, the partition structure 276 partitions the inside of the storage structure 270 to divide the flow path cross-sectional area of the storage structure 270 into the eight flow paths 280 such that the flow path cross-sectional areas of the two or more of the flow paths 280 (among the eight flow paths 280) are set to be the same. In such a manner, the partition structure 276 partitions the inside of the storage structure 270 so as not to impede the flow of the source gas. As a result, it is possible to achieve both a large flow rate supply (flash supply) and a heating for compensation for the temperature decrease (due to the adiabatic expansion) caused by such a flash supply.

In addition, when viewed from the gas flow direction, two or more partition structures 276 intersect with each other at the radial central portion 271 of the storage structure 270. Specifically, when viewed from the gas flow direction, the two or more partition structures 276 intersect with each other at the center C of the storage structure 270. In addition, according to the present embodiments, for example, four partition structures 276 intersect with each other at the center C of the storage structure 270. According to the present embodiments, since the two or more partition structures 276 intersect with each other at the center C of the storage structure 270, it can be said that the partition structures 276 extend radically (that is, in the radial direction) from the radial central portion 271 of the storage structure 270.

The piping heater 248 serving as a heating structure (heater) is provided on an outside (outer portion) of the storage structure 270. Specifically, the piping heater 248 is configured to heat an entirety of the storage 240a from the outside. In other words, the piping heater 248 is configured to heat the storage structure 270, the inlet structure 272 and the outlet structure 274 from the outside. The partition structure 276 is heated via the storage structure 270 which is heated by the piping heater 248. Specifically, the partition structure 276 is heated by a thermal conduction from the storage structure 270.

As shown in FIGS. 5A and 5B, the partition structure 276 according to the present embodiments extends linearly when viewed from the gas flow direction. However, the technique of the present disclosure is not limited to such a configuration. For example, the partition structure 276 may extend in a curved shape (including an arc shape or a wave shape), or may extend in a zigzag shape when viewed from the gas flow direction.

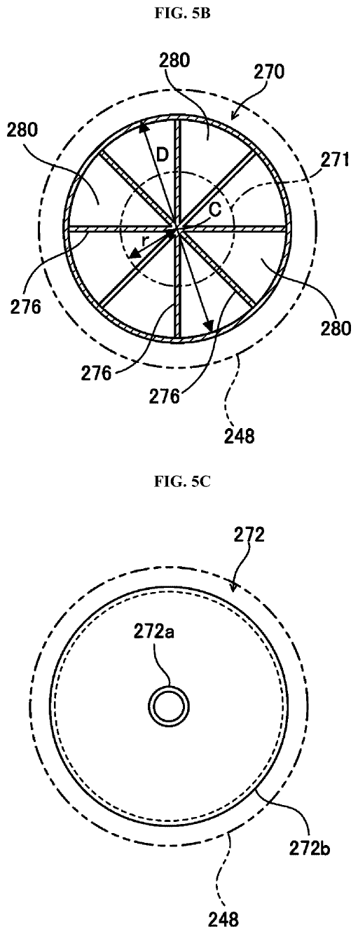

For example, as shown in FIG. 6A, the inside of the storage structure 270 may be partitioned by partition structures 286 instead of the partition structures 276. Specifically, the storage 240a includes the partition structures 286. When viewed from the gas flow direction, two or more partition structures 286 are arranged parallel to each other inside the storage structure 270. More specifically, three partition structures 286 divide (or partition) the inside of the storage structure 270 when viewed from the gas flow direction. The three partition structures 286 are arranged parallel to one another. A partition structure 286a located in a center of the three partition structures 286 passes through the radial central portion 271. For example, the partition structure 286a located in the center of the three partition structures 286 passes through the center C. In addition, the inside of the storage structure 270 is partitioned by the partition structure 286a and two partition structures 286b with the partition structure 286a interposed therebetween such that flow path cross-sectional areas of flow paths 288a are the same. Specifically, one of the flow paths 288a is formed between the partition structure 286a and one of the two partition structures 286b related thereto, and the other one of the flow paths 288a is formed between the partition structure 286a and the other one of the two partition structures 286b related thereto. In addition, the inside of the storage structure 270 is partitioned by the two partition structures 286b such that flow path cross-sectional areas of flow paths 288b are set to be the same. Specifically, one of the flow paths 288b is formed between an inner wall of the storage structure 270 and one of the two partition structures 286b related thereto, and the other one of the flow paths 288b is formed between the inner wall of the storage structure 270 and the other one of the two partition structures 286b related thereto.

For example, as shown in FIG. 6B, the inside of the storage structure 270 may be partitioned by partition structures 296 instead of the partition structures 286. Specifically, the storage 240a includes the partition structures 296. Specifically, for example, five partition structures 296 divide the inside of the storage structure 270 when viewed from the gas flow direction. The five partition structures 296 are arranged parallel to one another. A partition structure 296a located in a center of the five partition structures 296 passes through the radial central portion 271. For example, the partition structure 296a located in the center of the five partition structures 296 passes through the center C. In addition, among the five partition structures 296, two partition structures 296b facing both sides of the partition structure 296a also pass through the radial central portion 271. In addition, the inside of the storage structure 270 is partitioned by the partition structure 296a and the two partition structures 296b facing both sides of the partition structure 296a such that flow path cross-sectional areas of flow paths 298a are set to be the same. Specifically, one of the flow paths 298a is formed between the partition structure 296a and one of the two partition structures 296b related thereto, and the other one of the flow paths 298a is formed between the partition structure 296a and the other one of the two partition structures 296b related thereto. In addition, the inside of the storage structure 270 is partitioned by the two partition structures 296b such that flow path cross-sectional areas of flow paths 298b are set to be the same. Specifically, one of the flow paths 298b is formed between one of the two partition structures 296b related thereto and one of two partition structures 296c related thereto, and the other one of the flow paths 298b is formed between the other one of the two partition structures 296b related thereto and the other one of the two partition structures 296c related thereto. In addition, one of the two partition structures 296c is provided between the inner wall of the storage structure 270 and one of the two partition structures 296b related thereto, and the other one of the two partition structures 296c is provided between the inner wall of the storage structure 270 and the other one of the two partition structures 296b related thereto. In addition, the inside of the storage structure 270 is partitioned by the two partition structures 296c such that flow path cross-sectional areas of flow paths 298c are set to be the same. Specifically, one of the flow paths 298c is formed between the inner wall of the storage structure 270 and one of the two partition structures 296c related thereto, and the other one of the flow paths 298b is formed between the inner wall of the storage structure 270 and the other one of the two partition structures 296c related thereto. When the storage structure 270 is viewed from the gas flow direction, the spacing (gap or distance) between adjacent partition structures 296 away from the radial central portion 271 in the radical direction is wider than the spacing between adjacent partition structures 296 in the central portion 271. Specifically, the spacing between the partition structure 296a and its corresponding one of the partition structures 296b is wider than the spacing between one of the partition structure 296b and its corresponding one of the partition structures 296c related thereto. For example, the spacing is indicated by a symbol L in FIG. 6B.

For example, as shown in FIG. 6C, the inside of the storage structure 270 may be partitioned by partition structures 306 instead of the partition structures 276. Specifically, the storage 240a includes the partition structures 306 and partition structures 308 that intersect with the partition structures 306. Specifically, for example, five partition structures 306 and five partition structures 308 that intersect with the partition structures 306 divide the inside of the storage structure 270 when viewed from the gas flow direction. The five partitions 306 are arranged parallel to one another. A partition structure 306a located in a center of the five partition structures 306 passes through the radial central portion 271. For example, the partition structure 306a located in the center of the five partition structures 306 passes through the center C. In addition, the spacing (gap or distance) between the partition structure 306b and its corresponding one of partition structures 306c is wider than the spacing between one of the partition structure 306a and its corresponding one of partition structures 306b related thereto. In addition, the five partitions 308 are arranged parallel to one another. A partition structure 308a located in a center of the five partition structures 308 passes through the radial central portion 271. For example, the partition structure 308a located in the center of the five partition structures 308 passes through the center C. In addition, the spacing (gap or distance) between the partition structure 308b and its corresponding one of partition structures 308c is wider than the spacing between one of the partition structure 308a and its corresponding one of partition structures 308b related thereto. According to the present embodiments, the inside of the storage structure 270 is partitioned such that a flow path cross-sectional area of a flow path (among flow paths formed by the partition structures 306 and the partition structures 308) becomes narrower as it gets closer to the center C and becomes wider as it gets farther from the center C.

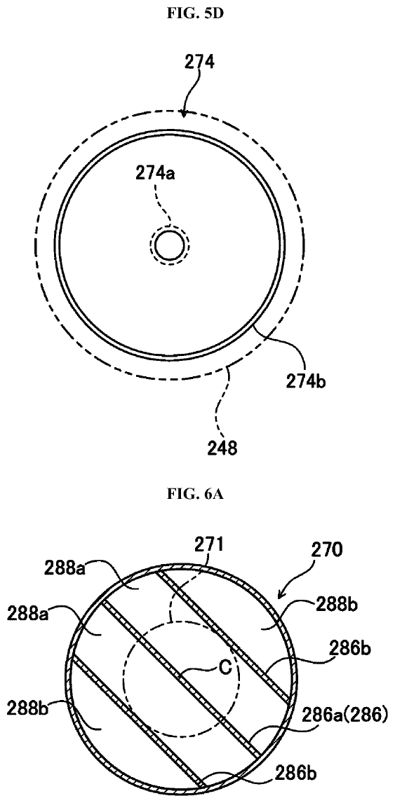

For example, as shown in FIG. 7, the inside of the storage structure 270 may be partitioned by partition structures 316 instead of the partition structures 276. The partition structures 316 are provided with a central heater (which is a central heating structure) 314. The central heater 314 is provided in the radial central portion 271 of the storage structure 270, and extends in the axial direction of the storage structure 270. The partition structures 316 extend radially from the central heater 314. According to the present embodiments, for example, eight partition structures 316 are provided. A cross-sectional area of the central heater 314 is set to be greater than a cross-sectional area of each of the partition structures 316. Inside the storage structure 270, a plurality of flow paths 318 are formed by the partition structures 316 and the central heater 314. According to the present embodiments, for example, the central heater 314 is of a circular column shape. However, the technique of the present disclosure is not limited to such a shape. For example, the central heater 314 may be of a cylindrical shape.

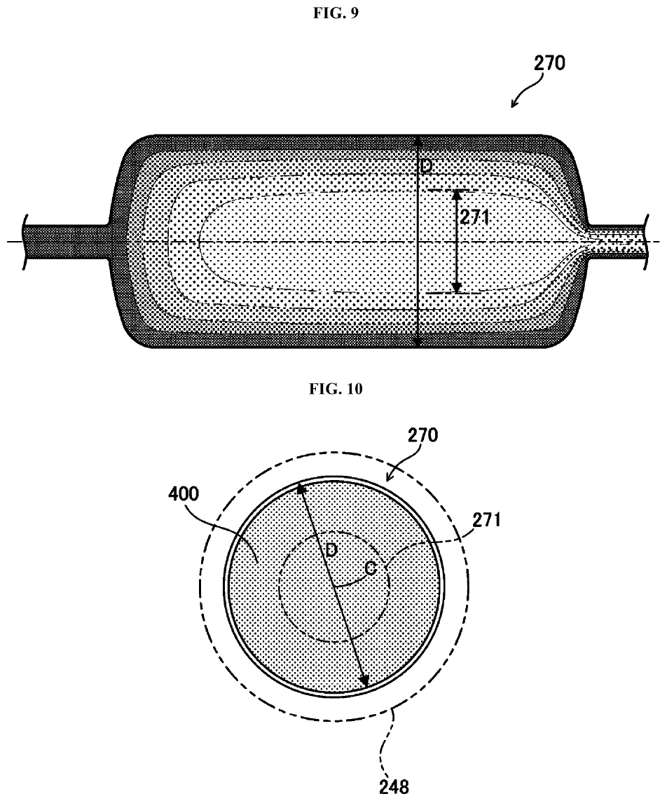

For example, as shown in FIG. 10, a filter (which is a filter structure) 400 may be installed inside the storage structure 270 instead of the partition structure 276. As the filter 400, for example, a metal fiber material (steel wool, for example) may be used. By providing the filter 400, it is possible to remove impurities from the source gas.

Although not shown, in the examples of FIG. 5A, FIGS. 6A to 6C, and FIG. 7, as the filter 400, a filter may be installed in each flow path, a filter may be installed inside the boundary structure 274b, a filter may be installed inside the connecting structure 272b, a filter may be installed inside both the boundary structure 274b and the connecting structure 272b, or a filter may be provided by a combination thereof.

By closing the valve 242a and opening the valve 243a, it is possible to fill the gas whose flow rate is adjusted by the MFC 241a into the storage 240a. When a predetermined amount of the gas is filled in the storage 240a and a pressure (inner pressure) of the storage 240a reaches a predetermined pressure, by closing the valve 243a and opening the valve 242a, it is possible to supply the gas (whose pressure is high) filled in the storage 240a to the process chamber 201 via the gas supply pipe 232a and the nozzle 249a. That is, it is possible to perform the flash supply of the gas whose pressure is high. For example, when the flash supply is being performed, the valve 243a may be open. An effect of the temperature decrease due to the adiabatic expansion caused by such a flash supply will be described later.

MFCs 241b and 241c and valves 243b and 243c serving as opening/closing valves are sequentially installed at the gas supply pipes 232b and 232c, respectively, in this order from upstream sides to downstream sides of the gas supply pipes 232b and 232c in the gas flow direction. A gas supply pipe 232e is connected to the gas supply pipe 232b at a downstream side of the valve 243b of the gas supply pipe 232b. An MFC 241e and a valve 243e are sequentially installed at the gas supply pipe 232e in this order from an upstream side to a downstream side of the gas supply pipe 232e in the gas flow direction. For example, each of the gas supply pipes 232b, 232c and 232e is made of a metal material such as SUS.

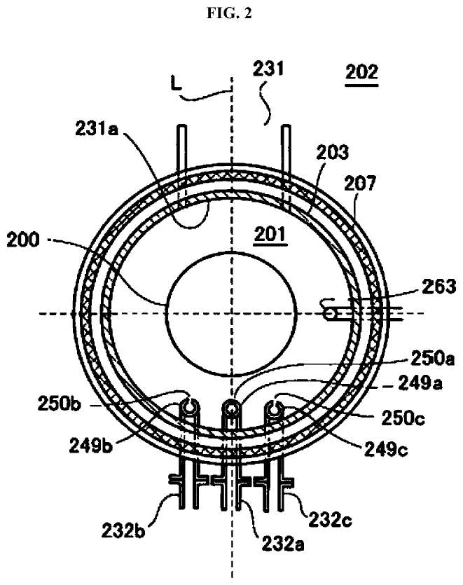

As shown in FIG. 2, each of the nozzles 249a to 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along an arrangement direction of the wafers 200). That is, each of the nozzles 249a to 249c is installed in a region that is located beside and horizontally surrounds a wafer arrangement region in which the wafers 200 are arranged (stacked) to extend along the wafer arrangement region. When viewed from above, the nozzle 249a is arranged so as to face an exhaust port 231a described later along a straight line (denoted by “L” shown in FIG. 2) with a center of the wafer 200 in the process chamber 201 interposed therebetween. The nozzles 249b and 249c are arranged along the inner wall of the reaction tube 203 (that is, along an outer periphery of the wafer 200) such that the straight line L passing through the nozzle 249a and a center of the exhaust port 231a is interposed therebetween. The straight line L may also be referred to as a straight line passing through the nozzle 249a and the center of the wafer 200. That is, it can be said that the nozzle 249c is provided opposite to the nozzle 249b with the straight line L interposed therebetween. The nozzles 249b and 249c are arranged line-symmetrically (that is, in a line symmetry) with respect to the straight line L serving as an axis of symmetry. A plurality of gas supply holes 250a, a plurality of gas supply holes 250b and a plurality of gas supply holes 250c are provided at side surfaces of the nozzles 249a, 249b and 249c, respectively. Gases are supplied via the gas supply holes 250a, the gas supply holes 250b and the gas supply holes 250c, respectively. The gas supply holes 250a, the gas supply holes 250b and the gas supply holes 250c are open toward (that is, open to face) the exhaust port 231a when viewed from above, and are configured such that the gases are supplied toward the wafers 200 via the gas supply holes 250a, the gas supply holes 250b and the gas supply holes 250c, respectively. The gas supply holes 250a, the gas supply holes 250b and the gas supply holes 250c are provided from the lower portion toward the upper portion of the reaction tube 203.

The source gas is supplied into the process chamber 201 through the gas supply pipe 232a provided with the MFC 241a, the valve 243a, the storage 240a, the valve 242a and the nozzle 249a.

A reactive gas is supplied into the process chamber 201 through the gas supply pipe 232b provided with the MFC 241b and the valve 243b and the nozzle 249b. In addition, the reactive gas is a substance whose molecular structure (chemical structure) is different from that of the source gas.

An inert gas is supplied into the process chamber 201 via the gas supply pipes 232d and 232e provided with the MFCs 241d and 241e and the valves 243d and 243e, respectively, the gas supply pipes 232a and 232b and the nozzles 249a and 249b. In addition, the inert gas is supplied into the process chamber 201 through the gas supply pipe 232c provided with the MFC 241c and the valve 243c and the nozzle 249c. For example, the inert gas may act as a purge gas, a carrier gas, a dilution gas and the like.

A source gas supplier (which is a source gas supply system) is constituted mainly by the gas supply pipe 232a, the MFC 241a, the valves 243a and 242a and the storage 240a. The source gas supplier may also be referred to as the “source gas supply line”. A reactive gas supplier (which is a reactive gas supply system) is constituted mainly by the gas supply pipe 232b, the MFC 241b and the valve 243b. The reactive gas supplier may also be referred to as a “reactive gas supply line”. An inert gas supplier (which is an inert gas supply system) is constituted mainly by the gas supply pipes 232c to 232e, the MFCs 241c to 241e and the valves 243c to 243e. The inert gas supplier may also be referred to as an “inert gas supply line”.

One or both of the source gas and the reactive gas may also be referred to as a “film forming gas”, and one or both of the source gas supplier and the reactive gas supplier may also be referred to as a “film forming gas supplier” (which is a film forming gas supply system). The film forming gas supplier may also be referred to as a “film forming gas supply line”.

Any one or an entirety of the gas suppliers described above may be configured as an integrated gas supply system 260 in which the components such as the valves 243a, 242a, 243b to 243e, the storage 240a and the MFCs 241a to 241e are integrated. The integrated gas supply system 260 is configured such that operations such as an operation of opening and closing the valves 243a, 242a, 243b to 243e and operations of adjusting flow rates of the gases by the MFCs 241a to 241e can be controlled by a controller 121 described later.

The exhaust port 231a through which an atmosphere (inner atmosphere) of the process chamber 201 is exhausted is provided at a lower side wall of the reaction tube 203. An exhaust pipe 231 is connected to the exhaust port 231a. For example, the exhaust pipe 231 is made of a metal material such as SUS. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) configured to detect a pressure (inner pressure) of the process chamber 201, and the APC valve 244 serves as a pressure regulator (pressure adjusting structure). With the vacuum pump 246 in operation, the APC valve 244 may be opened or closed to perform a vacuum exhaust operation for the process chamber 201 or stop the vacuum exhaust operation. In addition, with the vacuum pump 246 in operation, the inner pressure of the process chamber 201 may be adjusted by adjusting an opening degree of the APC valve 244 based on pressure information detected by the pressure sensor 245. An exhauster (which is an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate a boat 217 described later is provided under the seal cap 219. For example, a rotating shaft 255 of the rotator 267 is connected to the boat 217 through the seal cap 219. For example, the rotating shaft 255 is made of a metal material such as SUS. The rotator 267 is configured to rotate the wafers 200 accommodated in the boat 217 by rotating the boat 217. The seal cap 219 is configured to be elevated or lowered in a vertical direction by a boat elevator 115 serving as an elevating structure provided outside the reaction tube 203. The boat elevator 115 serves as a transfer apparatus (which is a transfer structure) capable of transferring (loading) the wafers 200 into the process chamber 201 and capable of transferring (unloading) the wafers 200 out of the process chamber 201 by elevating and lowering the seal cap 219.

A shutter 219s serving as a furnace opening lid capable of airtightly sealing (closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 serving as a substrate support is configured such that the plurality of wafers 200 (for example, 25 wafers to 200 wafers) are supported (or stacked) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are stacked in the vertical direction with a predetermined interval therebetween. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 can be adjusted based on temperature information detected by the temperature sensor 263 such that a desired temperature distribution of a temperature (inner temperature) of the process chamber 201 can be obtained. The temperature sensor 263 is provided along the inner wall of the reaction tube 203.

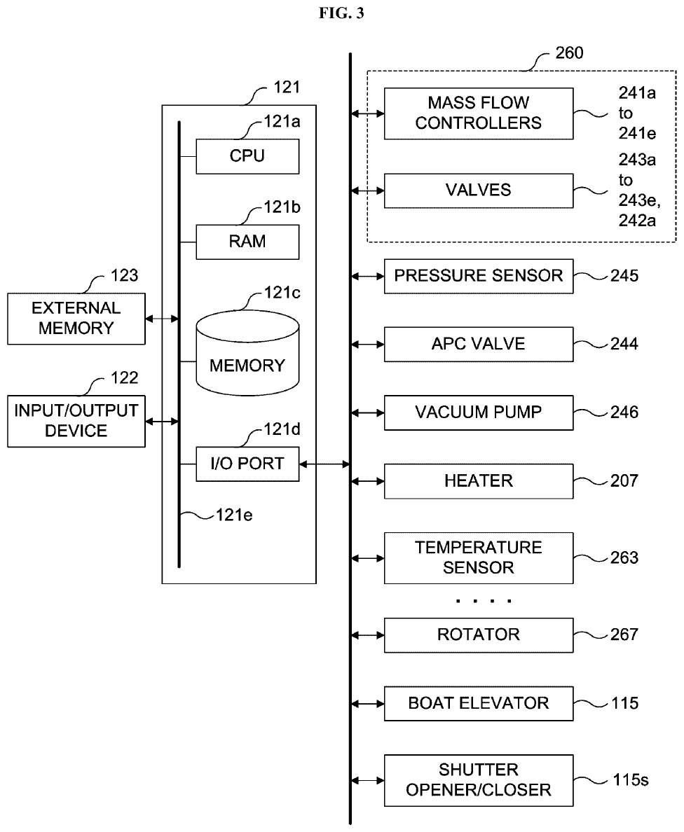

As shown in FIG. 3, the controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d are configured to be capable of exchanging data with the CPU 121a through an internal bus 121e. For example, an input/output device 122 constituted by a component such as a touch panel is connected to the controller 121.

For example, the memory 121c is configured by a component such as a flash memory, a hard disk drive (HDD) and a solid state drive (SSD). For example, a control program configured to control an operation of the substrate processing apparatus and a process recipe containing information on procedures and conditions of a substrate processing described later may be readably stored in the memory 121c. The process recipe is obtained by combining steps (procedures) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a to 241e, the valves 243a, 242a, 243b to 243e, the pressure sensor 245, the APC valve 244, the vacuum pump 246, the temperature sensor 263, the heater 207, the rotator 267, the boat elevator 115 and the shutter opener/closer 115s.

The CPU 121a is configured to read the control program from the memory 121c and execute the control program read from the memory 121c. In addition, the CPU 121a is configured to read the recipe from the memory 121c, for example, in accordance with an operation command inputted from the input/output device 122. In accordance with contents of the recipe read from the memory 121c, the CPU 121a may be configured to be capable of controlling various operations such as flow rate adjusting operations for various gases by the MFCs 241a to 241e, opening and closing operations of the valves 243a, 242a, 243b to 243e, an opening and closing operation of the APC valve 244, a pressure adjusting operation by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program stored in an external memory 123 into the computer. For example, the external memory 123 may include a magnetic disk such as the HDD, an optical disk such as a CD, a magneto-optical disk such as an MO and a semiconductor memory such as a USB memory and the SSD. The memory 121c or the external memory 123 may be embodied by a non-transitory computer readable recording medium.

Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program to the computer.

### (2) Substrate Processing

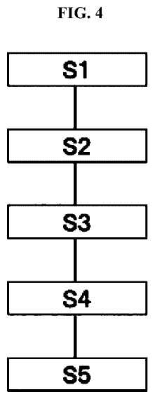

Hereinafter, an example of a process sequence of processing the wafer 200 serving as the substrate by using the substrate processing apparatus described above, which is a part of a manufacturing process of a semiconductor device, will be described mainly with reference to FIG. 4. For example, as the process sequence, a film forming sequence of forming a film on the wafer 200 will be described. In the following description, operations of components constituting the substrate processing apparatus are controlled by the controller 121.

According to the film forming sequence of the present embodiments, the film is formed on the wafer 200 by performing a cycle a predetermined number of times (n times, n is an integer of 1 or more). The cycle may include: a step A of supplying the source gas through the source gas supply line to the process chamber 201 in which the wafer 200 is accommodated; and a step B of supplying the reactive gas to the process chamber 201 in which the wafer 200 is accommodated.

In the film forming sequence of the present embodiments, when the source gas is supplied, the source gas is pre-filled in the storage 240a provided in the source gas supply line before being supplied to the process chamber 201. However, the source gas may be supplied to the process chamber 201 without pre-filling the storage 240a by selecting an appropriate supply method in accordance with a sequence.

In addition, in the film forming sequence of the present embodiments, when the step A and the step B are alternately performed n times (n is an integer of 1 or more), a step of purging the process chamber 201 is preferably inserted between the step A and the step B. In addition, in the present specification, the term “purge” refers to an operation of removing the source gas and an intermediate present in the process chamber 201 by supplying the inert gas to the process chamber 201, and the term “exhaust” refers to an operation of removing the source gas and the intermediate present in the process chamber 201 without supplying the inert gas to the process chamber 201.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on another layer (or another film) formed on a wafer”. In the present specification, the terms “substrate” and “wafer” may be used as substantially the same meaning.

### <Substrate Loading Step S1: Wafer Charging Step and Boat Loading Step>

The plurality of wafers 200 are charged (loaded or transferred) into the boat 217 (wafer charging step). Thereafter, the shutter 219s is moved by the shutter opener/closer 115s to open the lower end opening of the manifold 209 (shutter opening step). Then, as shown in FIG. 1, the boat 217 supporting the wafers 200 is elevated by the boat elevator 115 and loaded (transferred) into the process chamber 201 (boat loading step). In such a state, the seal cap 219 airtightly seals (or closes) the lower end opening of the manifold 209 via the O-ring 220b.

### <Pre-Processing Step S2: Pressure Adjusting Step and Temperature Adjusting Step>

After the boat loading step is completed, the vacuum pump 246 vacuum-exhausts (decompresses and exhausts) an atmosphere (inner atmosphere) of the process chamber 201 (that is, a space in which the wafers 200 are present (accommodated)) such that the inner pressure of the process chamber 201 reaches and is maintained at a desired pressure (vacuum degree). In such an operation, the inner pressure of the process chamber 201 is measured by the pressure sensor 245, and the APC valve 244 is feedback-controlled based on the pressure information detected by the pressure sensor 245 (pressure adjusting step). In addition, the heater 207 heats the process chamber 201 such that a temperature of the wafer 200 in the process chamber 201 reaches and is maintained at a desired process temperature. In such an operation, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### <Substrate Processing Step S3: Film Forming Process>

Then, the following steps A and B are sequentially performed in this order.

### <Step A>

In the present step, the source gas is supplied to the wafer 200 in the process chamber 201. Specifically, the valve 242a is closed and the valve 243a is opened to supply the source gas into the gas supply pipe 232a. A flow rate of the source gas is adjusted by the MFC 241a, and the source gas whose flow rate is adjusted is supplied into the storage 240a. Thereby, the source gas is filled in the storage 240a. When a predetermined amount of the source gas is filled into the storage 240a, the valve 243a is closed to maintain a state in which the storage 240a is filled with the source gas.

In the present step, the valve 242a is opened to supply the source gas (whose pressure is high) filled in the storage 240a into the process chamber 201 at once. As a result, the source gas is supplied to the wafer 200 at once (that is, the flash supply of the source gas is performed). In the flash supply, due to a pressure difference between the storage 240a and the process chamber 201, the source gas ejected through the nozzle 249a into the process chamber 201 is accelerated to, for example, the sonic speed (340 m/sec), and a speed of the source gas on the wafer 200 also reaches about several tens of m/sec. In such an operation, the valve 243a is opened. In addition, the valves 243c to 243e may be opened to supply the inert gas to the process chamber 201 through each of the nozzles 249a to 249c. In addition, the present step is preferably performed with the exhauster substantially fully closed (that is, with the APC valve 244 substantially fully closed). In the present specification, the term “substantially closed” (“substantially fully closed”) may refer to a state in which the APC valve 244 is open by 0.1% to several %, or may refer a state in which the gas is still being exhausted through the exhauster even when the APC valve 244 is controlled to be 100% closed.

Subsequently, in the present step, the valves 243a and 242a are closed to stop a supply of the source gas to the process chamber 201. Then, for example, with the APC valve 244 fully opened, the inner atmosphere of the process chamber 201 is vacuum-exhausted to remove a substance (such as the gas remaining in the process chamber 201) out of the process chamber 201.

### <Step B>

After the step A is completed, the reactive gas is supplied to the wafer 200 in the process chamber 201, that is, to a first layer (for example, a silicon (Si)-containing layer) formed on the wafer 200.

Specifically, the valve 243b is opened to supply the reactive gas into the gas supply pipe 232b. A flow rate of the reactive gas is adjusted by the MFC 241b, and the reactive gas whose flow rate is adjusted is supplied into the process chamber 201 through the nozzle 249b, and is exhausted through the exhaust port 231a. Thereby, the reactive gas is supplied to the wafer 200 (reactive gas supply step). In the present step, the valves 243c to 243e may be opened to supply the inert gas into the process chamber 201 through each of the nozzles 249a through 249c.

For example, when a nitriding gas described later is used as the reactive gas, by supplying the nitriding gas to the wafer 200 under process conditions related thereto, at least a part of the silicon-containing layer formed on the wafer 200 is nitrided (modified). As a result, a second layer is formed on an uppermost surface of the wafer 200 serving as a base. For example, the second layer formed by nitriding the silicon-containing layer is a silicon nitride layer (SiN layer) serving as a layer containing silicon and nitrogen (N).

After the silicon nitride layer serving as the second layer is formed, the valve 243b is closed to stop a supply of the nitriding gas (reactive gas) into the process chamber 201. Then, by process procedures similar to those of the step A described above, a substance (such as the gas remaining in the process chamber 201) is removed out of the process chamber 201 (purge step).

### <Performing Cycle Predetermined Number of Times>

By performing the cycle including the steps A and B a predetermined number of times (n times, wherein n is an integer of 1 or more), it is possible to form the film (such as a silicon nitride film (SiN film)) on the surface of the wafer 200. It is preferable that the cycle described above is performed a plurality number of times. It is preferable that the cycle described above is repeatedly performed a plurality number of times. That is, it is preferable that the cycle is repeatedly performed the plurality number of times until a thickness of the silicon nitride film reaches a desired thickness while a thickness of the silicon nitride layer formed per each cycle is smaller than the desired thickness. In such an operation, in the step A, it is preferable that an amount of the source gas pre-filled into the storage 240a is a constant amount for each cycle. In addition, in a second and subsequent runs (executions) of the cycle, it is preferable that a filling operation of the source gas into the storage 240a in the step A is performed in parallel with the supply of the reactive gas in the step B in a previous run (execution) of the cycle.

In the present embodiments, as the source gas, for example, a silane-based gas containing silicon (Si) serving as a main element (primary element) constituting the film to be formed on the wafer 200 may be used. As the silane-based gas, for example, a gas containing silicon and a halogen element, that is, a halosilane gas may be used. The halogen element includes an element such as chlorine (Cl), fluorine (F), bromine (Br) and iodine (I). As the halosilane gas, for example, a chlorosilane gas containing silicon and chlorine may be used.

As the source gas, for example, the chlorosilane gas such as monochlorosilane (SiH₃Cl) gas, dichlorosilane (SiH₂Cl₂) gas, trichlorosilane (SiHCl₃) gas, tetrachlorosilane (SiCl₄) gas, hexachlorodisilane (HCDS) (Si₂Cl₆) gas and octachlorotrisilane (Si₃Cl₈) gas may be used. For example, one or more of the gases exemplified above as the chlorosilane gas may be used as the source gas.

As the inert gas, for example, nitrogen (N₂) gas or a rare gas such as argon (Ar) gas, helium (He) gas, neon (Ne) gas and xenon (Xe) gas may be used. For example, one or more of the gases exemplified above may be used as the inert gas. The same also applies to each step described later.

As the reactive gas, for example, a gas containing nitrogen (N) and hydrogen (H), that is, the nitriding gas (nitriding agent) may be used. The gas containing nitrogen and hydrogen serves as a nitrogen-containing gas, and also serves as a hydrogen-containing gas. It is preferable that the gas containing nitrogen and hydrogen contains a nitrogen-hydrogen bond (N—H bond).

As the reactive gas, for example, a hydrogen nitride-based gas such as ammonia (NH₃) gas, diazene (N₂H₂) gas, hydrazine (N₂H₄) gas and N₃H₈ gas may be used. For example, one or more of the gases exemplified above may be used as the reactive gas.

### <Post-Processing Step S2: After-Purge Step and Returning to Atmospheric Pressure Step>

After the film of the desired thickness is formed on the wafer 200, the inert gas serving as the purge gas is supplied into the process chamber 201 through each of the nozzles 249a to 249c, and then is exhausted through the exhaust port 231a. Thereby, the process chamber 201 is purged with the inert gas. As a result, a substance such as the gas remaining in the process chamber 201 and reaction by-products remaining in the process chamber 201 is removed from the process chamber 201 (after-purge step). Thereafter, the inner atmosphere of the process chamber 201 is replaced with the inert gas (substitution by the inert gas), and the inner pressure of the process chamber 201 is returned to the normal pressure (returning to the atmospheric pressure step).

### <Substrate Unloading Step S5: Boat Unloading Step and Wafer Discharging Step>

Thereafter, the seal cap 219 is lowered by the boat elevator 115 and the lower end of the manifold 209 is opened. Then, the boat 217 with the wafers 200 (which are processed and supported in the boat 217) is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). Then, the wafers 200 (which are processed) are discharged (transferred or unloaded) from the boat 217 unloaded out of the reaction tube 203 (wafer discharging step).

### (3) Effect of Temperature Decrease Due to Adiabatic Expansion in Present Embodiments

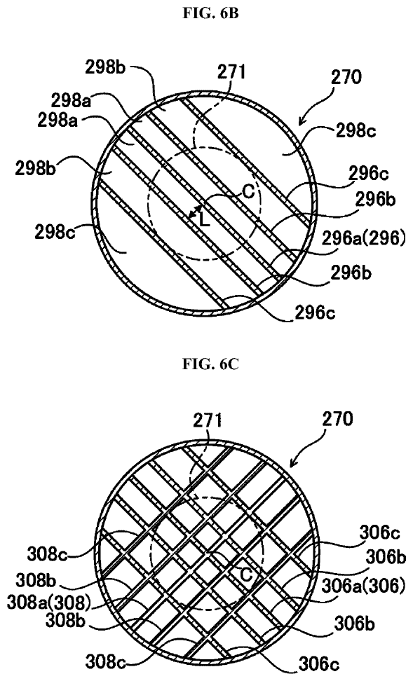

FIG. 8 is a graph schematically illustrating a relationship among a time elapsed after the flash supply, an inner pressure and a temperature (inner temperature) of a storage 240a according to a comparative example in which the partition structure is not provided in a storage structure of the storage 240a. A horizontal axis shown in FIG. 8 indicates the time, a vertical axis on a left side shown in FIG. 8 indicates the inner pressure, and a vertical axis on a right side shown in FIG. 8 indicates the inner temperature. In the graph of FIG. 8, a dashed line indicates the inner pressure, and a solid line indicates the inner temperature. As shown in FIG. 8, in the storage 240a in which the partition structure is not provided in the storage structure, the inner pressure is continuously decreased after the source gas is supplied, and saturates at a certain pressure. On the other hand, the inner temperature is decreased once, and then returns to an original temperature after a time has elapsed. In FIG. 8, the inner temperature is observed to decrease to a temperature range from about 150° C. to about 120° C.

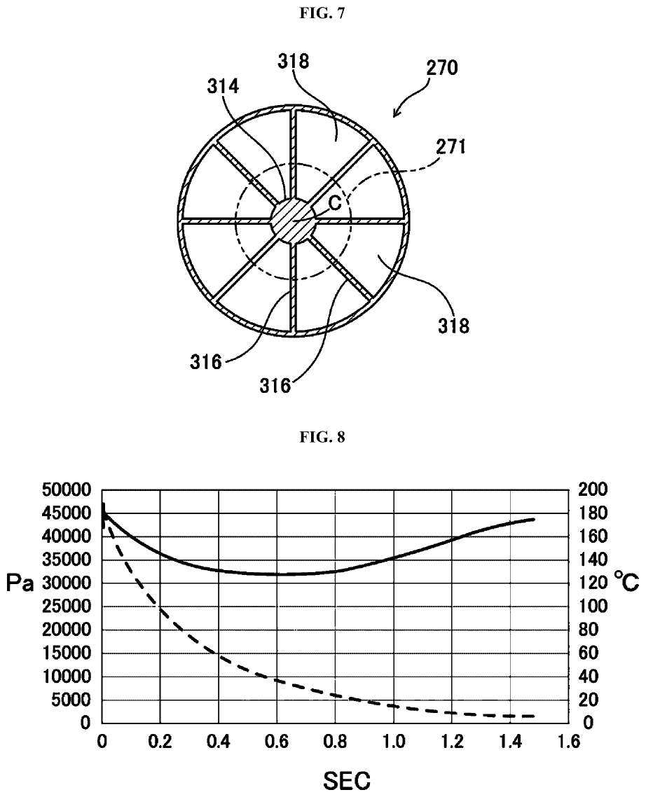

It is presumed that the temperature decrease mentioned above is due to the adiabatic expansion caused by the flash supply. In addition, although the storage 240a is heated by the piping heater 248 provided outside the storage 240a, the inner temperature decreases momentarily. As shown in FIG. 9, since the piping heater 248 is provided with respect to the entire storage 240a, the temperature decrease does not occur in the inner wall of the storage structure 270. However, in the radial central portion 271 of the storage 240a, which is less affected by the heating of the heater (that is, the piping heater 248), the temperature decrease occurs. Depending on a saturated vapor pressure of the source gas, a re-liquefaction or a re-solidification may occur.

### (4) Effects According to Present Embodiments

According to the present embodiments, it is possible to obtain one or more of the following effects.

(a) By providing the partition structure 276 in the storage 240a (that is, in the storage structure 270) so as not to impede the flow of the source gas, it is possible to achieve both the large flow rate supply (flash supply) and the heating for compensation for the temperature decrease (due to the adiabatic expansion) caused by the flash supply.

(b) Even when the temperature decrease occurs in the radial central portion 271 of the storage container (that is, the storage 240a) due to the effect of the adiabatic expansion and the like after the flash supply of the source gas, it is possible to heat the partition structure 276 immediately by utilizing the thermal conduction.

(c) Since the partition structure 276 is arranged in the radial central portion 271 of the storage 240a (that is, the storage structure 270), it is possible to reduce the temperature decrease due to the adiabatic expansion caused by the large flow rate supply.

(d) Since the partition structures 276 can be arranged in a concentrated manner in the radial central portion 271 of the storage 240a (storage structure 270), it is possible to reduce the temperature drop due to the adiabatic expansion caused by the large flow rate supply.

(e) In the step A, the source gas is filled in advance in the storage 240a provided in the source gas supply line, and then supplied to the wafer 200 in the process chamber 201. In other words, a large amount of the source gas is supplied at once in a very short time (that is, the flash supply is performed). Thereby, it is possible to uniformly adsorb a first intermediate (for example, SiClₕ when the source gas is the HCDS gas) over an entirety of the surface of the wafer 200, and to suppress an adsorption of a second intermediate (for example, SiCl₄ when the source gas is the HCDS gas) to the surface of the wafer 200. As a result, it is possible to improve a step coverage of the film formed on the wafer 200 and a thickness uniformity of the film within the surface thereof.

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

For example, the embodiments mentioned above are described by way of an example in which a cross-sectional shape of the storage 240a is a circular shape. However, the technique of the present disclosure may be preferably applied regardless of whether the cross-sectional shape is, for example, a polygon (triangle or more) shape, an ellipse shape, a star shape, an alphabet character shape such as an L shape, a dome shape, a cone shape, a polygonal pyramid shape, or a concave-convex shape. Even in such a case, it is possible to obtain at least a part of the effects of the embodiments mentioned above.

For example, the embodiments mentioned above are described by way of an example in which a large amount of the source gas is supplied at once in a very short time (that is, the flash supply is performed) in the step A. However, for example, the source gas may be supplied to the process chamber 201 without being filled in the storage 240a in advance (that is, a non-flash supply of the source gas may be performed).

Before such a step (that is, before the step A), the valves 243a and 242a are closed to prevent the source gas from being supplied to the storage 240a. Then, in the step A, the valves 243a and 242a are opened to supply the source gas into the gas supply pipe 232a. The flow rate of the source gas is adjusted by the MFC 241a, and the source gas whose flow rate is adjusted is supplied into the process chamber 201 through the valve 243a, the storage 240a, the valve 242a and the nozzle 249a. Thereby, the source gas is supplied to the wafer 200 (that is, the non-flash supply of the source gas is performed). In such a case, the speed of the source gas on the wafer 200 is set to be smaller than the speed of the source gas on the wafer 200 in the flash supply. When supplying the source gas, the valves 243c to 243e may be opened to supply the inert gas into the process chamber 201 through each of the nozzles 249a to 249c. In addition, when the non-flash supply of the source gas is performed, instead of fully closing the APC valve 244, the APC valve 244 may be set to a state between a fully closed state and a fully opened state such that the inner pressure of the process chamber 201 reaches and is maintained at a predetermined pressure.

For example, the embodiments mentioned above are described by way of an example in which the chlorosilane gas is used as the source gas. However, the technique of the present disclosure is not limited thereto. As the source gas, for example, instead of or in addition to the chlorosilane gas, a fluorosilane gas such as tetrafluorosilane (SiF₄) gas and difluorosilane (SiH₂F₂) gas, a bromosilane gas such as tetrabromosilane (SiBr₄) gas and dibromosilane (SiH₂Br₂) gas, or an iodine silane gas such as tetraiodide silane (SiI₄) gas and diiodosilane (SiH₂I₂) gas is used as the source gas. For example, one or more of the gases exemplified above may be used as the source gas.

As the source gas, for example, instead of or in addition to the gases exemplified above, a gas containing silicon and an amino group, that is, an aminosilane gas may be used. The amino group refers to a monovalent functional group obtained by removing hydrogen (H) from ammonia, a primary amine or a secondary amine, and may be expressed as “—NH₂”, “—NHR” or “—NR₂”. In addition, “R” represents an alkyl group, and two “R”s of “—NR₂” may be the same or different.

As the source gas, for example, the aminosilane gas such as tetrakis (dimethylamino) silane (Si[N(CH₃)₂]₄, abbreviated as 4DMAS) gas, tris (dimethylamino) silane (Si[N(CH₃)₂]₃H, abbreviated as 3DMAS) gas, bis(diethylamino) silane (Si[N(C₂H₅)₂]H₂, abbreviated as BDEAS) gas, bis (tertiarybutylamino) silane gas (SiH₂[NH(C₄H₉)]₂, abbreviated as BTBAS) gas and (diisopropylamino) silane (SiH₃[N(C₃H₇)₂], abbreviated as DIPAS) gas may be used. For example, one or more of the gases exemplified above as the aminosilane gas may be used as the source gas.

For example, the embodiments mentioned above are described by way of an example in which the chlorosilane gas is used as the source gas, for example. However, the technique of the present disclosure is not limited thereto. For example, the technique of the present disclosure may be preferably applied when the source gas containing a metal element such as aluminum (Al), titanium (Ti), hafnium (Hf), zirconium (Zr), tantalum (Ta), molybdenum (Mo) and tungsten (W) is used to form a film containing the metal element on the substrate by using the film forming sequence mentioned above. As the film containing the metal element, for example, a film such as an aluminum nitride film (AlN film), a titanium nitride film (TiN film), a hafnium nitride film (HfN film), a zirconium nitride film (ZrN film), a tantalum nitride film (TaN film), a molybdenum nitride film (MoN film), a tungsten nitride film (WN film), an aluminum oxide film (AlO film), a titanium oxide film (TiO film), a hafnium oxide film (HfO film), a zirconium oxide film (ZrO film), a tantalum oxide film (TaO film), a molybdenum oxide film (MoO film), a tungsten oxide film (WO film), a titanium oxynitride film (TiON film), a titanium aluminum carbonitride film (TiAlCN film), a titanium aluminum carbide film (TiAlC film) and a titanium carbonitride film (TiCN film) may be formed. Even in such a case, it is possible to obtain at least a part of the effects of the embodiments mentioned above.

For example, the embodiments mentioned above are described by way of an example in which the silicon nitride film (SiN film) or a silicon carbonitride film (SiCN film) is formed on the wafer 200 in the substrate processing. However, the technique of the present disclosure is not limited thereto. For example, the technique of the present disclosure may be preferably applied when a film containing silicon (such as a silicon oxynitride film (SiON film), a silicon oxycarbide film (SiOC film), a silicon oxycarbonitride film (SiOCN film), a silicon borocarbonitride film (SiBCN film), a silicon boronitride film (SiBN film) and a silicon oxide film (SiO film)) is formed instead of or in addition to the silicon nitride film or the silicon carbonitride film. Even in such a case, it is possible to obtain at least a part of the effects of the embodiments mentioned above.

The recipe mentioned above is not limited to creating a new recipe. For example, the recipe may be prepared by changing an existing recipe installed in the substrate processing apparatus in advance. When changing the existing recipe to a new recipe, the new recipe may be installed in the substrate processing apparatus via an electric communication line or a recording medium in which the new recipe is stored. In addition, the existing recipe already stored in the substrate processing apparatus may be directly changed to the new recipe by operating the input/output device 122 of the substrate processing apparatus.

For example, the embodiments mentioned above are described by way of an example in which a batch type substrate processing apparatus capable of simultaneously processing a plurality of substrates is used form the film. However, the technique of the present disclosure is not limited thereto. For example, the technique of the present disclosure may be preferably applied when a single wafer type substrate processing apparatus capable of processing one or several substrates at once is used to form the film. For example, the embodiments mentioned above are described by way of an example in which the substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

In addition, the embodiments and the modified examples mentioned above may be appropriately combined. The process procedures and the process conditions of each combination thereof may be substantially the same as those of the embodiments mentioned above or the modified examples mentioned above.

According to some embodiments of the present disclosure, it is possible to reduce the effect of the adiabatic expansion caused by the flash supply.

What is claimed is:

1. A storage container provided in a supply line through which a source gas is supplied to a process chamber, the storage container comprising:
a storage structure capable of storing the source gas therein, wherein a flow path cross-sectional area of the storage structure is set to be greater than that of the supply line; and
a partition structure arranged inside the storage structure along a gas flow direction, and configured to partition an inside of the storage structure by passing through a radial central portion of the storage structure when viewed from the gas flow direction such that a plurality of flow paths are formed.

2. The storage container of claim 1, wherein the partition structure is configured to partition the inside of the storage structure such that, among the plurality of flow paths, two or more flow paths whose flow path cross-sectional areas are the same are provided.

3. The storage container of claim 1, further comprising
one or more partition structures,
wherein two or more partition structures intersect with each other at the radial central portion of the storage structure when viewed from the gas flow direction.

4. The storage container of claim 1, further comprising
one or more partition structures,
wherein two or more partition structures are arranged parallel to one another when viewed from the gas flow direction.

5. The storage container of claim 1, further comprising
one or more partition structures,
wherein the partition structure and the one or more partition structures extend radically from the radial central portion of the storage structure.

6. The storage container of claim 1, further comprising
one or more partition structures,
wherein the partition structure and the one or more partition structures are configured such that a gap between adjacent partition structures away from the radial central portion of the storage structure is wider than a gap between adjacent partition structures in the radial central portion of the storage structure.

7. The storage container of claim 1, wherein the partition structure is provided with a central heater provided in the radial central portion of the storage structure and extending in an axial direction of the storage structure.

8. The storage container of claim 7, wherein a cross-sectional area of the central heater is set to be greater than a cross-sectional area of the partition structure.

9. The storage container of claim 1, wherein a heater is provided outside the storage structure, and the partition structure is heated via the storage structure heated by the heater.

10. The storage container of claim 1, further comprising
an inlet structure provided with: an introduction structure into which the source gas is introduced; and a connecting structure configured to connect the introduction structure and the storage structure; and
an outlet structure provided with: a release structure from which the source gas is ejected; and a boundary structure configured to connect the release structure and the storage structure,
wherein a flow path cross-sectional area of each of the introduction structure and the release structure is set to be same as that of the supply line.

11. The storage container of claim 10, wherein a filter for the source gas is installed inside one or both of the boundary structure and the connecting structure.

12. The storage container of claim 11, wherein a heater is provided outside the outlet structure, and the filter inside the boundary structure is heated via the boundary structure heated by the heater.

13. The storage container of claim 11, wherein a heater is provided outside the inlet structure, and the filter inside the connecting structure is heated via the connecting structure heated by the heater.

14. The storage container of claim 1, further comprising
a filter installed inside the storage structure and configured to filter the source gas.

15. The storage container of claim 14, further comprising
a heater provided at the storage structure,
wherein the filter is heated via the storage structure heated by the heater.

16. A substrate processing apparatus comprising:
a process chamber in which a substrate is processed; and
a storage container provided in a supply line through which a source gas is supplied to the process chamber,
wherein the storage container comprises:
a storage structure capable of storing the source gas therein, wherein a flow path cross-sectional area of the storage structure is set to be greater than that of the supply line; and
a partition structure arranged inside the storage structure along a gas flow direction, and configured to partition an inside of the storage structure by passing through a radial central portion of the storage structure when viewed from the gas flow direction such that a plurality of flow paths are formed.

17. The substrate processing apparatus of claim 16, wherein the storage container further comprises
a filter installed inside the storage structure and configured to filter the source gas.

18. A gas supply method comprising
supplying a source gas through a storage container provided in a supply line through which the source gas is supplied to a process chamber,
wherein the storage container comprises:
a storage structure capable of storing the source gas therein, wherein a flow path cross-sectional area of the storage structure is set to be greater than that of the supply line; and
a partition structure arranged inside the storage structure along a gas flow direction, and configured to partition an inside of the storage structure when viewed from the gas flow direction such that a plurality of flow paths are formed.

19. A gas supply method of claim 18, wherein the storage container further comprises
a filter installed inside the storage structure and configured to filter the source gas.

20. A method of manufacturing a semiconductor device, comprising
performing a predetermined processing by supplying the source gas to a substrate on which the semiconductor device is to be formed, using the gas supply method of claim 18.
